(19) United States
(12) Patent Application Publication
(10) Pub. No.: US 2026/0089945 A1
(43) Pub. Date: Mar. 26, 2026

(54) Discrete-type Multi Slit Cell with a Sacrificial Channel Cut by Non-conformal Oxide and Carbon Gap-fill

(71) Applicant: SK hynix Inc., Gyeonggi-do (KR)

(72) Inventors: Sungwon LIM, San Jose, CA (US); Tong ZHANG, San Jose, CA (US); Agus TJANDRA, San Jose, CA (US); Sung-Taeg KANG, San Jose, CA (US)

(21) Appl. No.: 18/898,495

(22) Filed: Sep. 26, 2024

(51) Int. Cl. H10B 43/27; G11C 16/04; H10B 43/10; H10B 43/35

(52) U.S. Cl. CPC H10B 43/27; G11C 16/0483; H10B 43/10; H10B 43/35

(57) ABSTRACT

A method for forming a split storage structure and an associated semiconductor memory device. The method forms oxide layers and nitride layers alternately stacked on a substrate, etches a hole through the oxide layers and the nitride layers, the hole having shorter axis sides and longer axis sides, etches the nitride layers to form recessed pockets between the oxide layers adjacent the longer axis sides, forms blocking layers and storage layers to fill the recessed pockets, forms a tunnel layer and a channel layer to cover walls of the storage layers; provides an incomplete gap-filling layer in the hole leaving open areas along the longer axis sides of the hole, removes a part of the channel layer to form a split channel layer; completely removes the nitride layers to form recesses between the oxide layers; and forms conductive layers in the recesses where the nitride layers were completely removed.

### BACKGROUND

### 1. Field

The present invention relates to semiconductor memory devices and fabrication techniques thereof.

### 2. Description of the Related Art

A semiconductor memory device may include a plurality of memory cells capable of storing data. These memory cells may be coupled in series between select transistors to form a plurality of memory strings. Gates of the memory cells and the select transistors forming the memory strings may be stacked on each other for high integration density of the semiconductor device. A three-dimensional semiconductor device may be realized by using a gate stack structure including the gates stacked on each other. With regard to the realization of such a three-dimensional semiconductor device including the gate stack structure, various techniques for improving the operational reliability of the semiconductor device are being developed.

Semiconductor technology has advanced at a rapid pace and device dimensions have shrunk with advancing technology to provide faster processing and storage per unit space. In NAND devices, the string current needs to be high enough to obtain sufficient current to differentiate ON and OFF cells. The string current is dependent on the carrier mobility which is enhanced by enlarging the grain size of the silicon channel.

In a NAND flash, memory cells may be connected in series and an address line may be installed as a block unit. The NAND flash has advantages such as relatively low manufacturing cost, fast write speed, and suitable use for a large capacity. The vertical NAND flash memory typically stack memory cells vertically and use charge trapping structures.

Various insulators (dielectrics), semiconductors, and conductor materials are applied to process NAND devices. As an insulator material, a silicon oxide, a silicon nitride, a silicon oxynitride, a high dielectric (high-k) material, etc. may be used, and as a semiconductor material, a single crystal silicon, a polycrystalline silicon, an amorphous silicon, a germanium, a silicon-germanium, and various other compound semiconductors may be used.

As cell density increases, there is a need to process even smaller dimensional structures from the insulating and semiconductor materials being used to construct the semiconductor memory devices. In this context, embodiments of the present invention arise.

### SUMMARY

In accordance with one embodiment of the invention, there is provided a method for forming a split storage structure. The method forms oxide layers and nitride layers alternately stacked on a substrate, etches the oxide layers and the nitride layers to form a hole having shorter axis sides and longer axis sides, etches the nitride layers to form recessed pockets between the oxide layers adjacent the longer axis sides, forms blocking layers and storage layers to fill the recessed pockets, forms a tunnel layer and a channel layer to cover vertical walls of the storage layers inside the hole; provides an incomplete gap-filling layer in the hole, the incomplete gap-filling layer leaving open areas along the longer axis sides of the hole, removes a part of the channel layer along the open areas to form a split channel layer, completely removes the nitride layers to form recess areas between the oxides, and forms conductive layers in the recess areas where the nitride layers were completely removed.

In accordance with another embodiment of the invention, there is provided a semiconductor memory device comprising: a split channel layer adjacent an asymmetric hole in a stacked structure; a tunnel oxide in contact with the split channel layer; a charge trap disposed in the stacked structure and in contact with the tunnel oxide, a blocking oxide disposed in a recess in the stacked structure adjacent the asymmetric hole and in contact with the charge trap, wherein the split channel layer is divided from a silicon channel layer using a non-oxidation process such that dimensions of the charge trap and the blocking layer from respective patterned dimensions are not changed due to additional oxidation

### BRIEF DESCRIPTION OF THE DRAWINGS

FIGS. 1A-1D are diagrams depicting processing an elliptical cell memory structure in accordance with embodiments of the present invention.

FIGS. 2A-2B are diagrams depicting further processing of the elliptical cell memory structure in accordance with embodiments of the present invention.

FIGS. 3A-3C are diagrams depicting further processing of the elliptical cell memory structure in accordance with embodiments of the present invention.

FIGS. 4A-4E are diagrams depicting further processing of the elliptical cell memory structure in accordance with embodiments of the present invention.

FIGS. 5A and 5B are a composite flowchart illustrating one method for forming a memory storage structure in accordance with embodiments of the present invention.

FIG. 6 is a schematic illustrating a multi-dimensional memory device in accordance with embodiments of the present invention.

FIG. 7 is a schematic illustrating a stacked memory structure in accordance with embodiments of the present invention.

FIGS. 8A to 8C are schematic diagrams of multi-site cell structures of a semiconductor memory device in accordance with embodiments of the present disclosure.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Throughout the disclosure, like reference numerals refer to like parts throughout the various figures and embodiments of the present invention.

A detailed description of one or more embodiments of the invention is provided below along with accompanying figures that illustrate the principles of the invention. The invention is described in connection with such embodiments, but the invention is not limited to any embodiment. The scope of the invention encompasses numerous alternatives, modifications and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

To continue advanced NAND technology scaling, there is a need to have breakthrough in terms of cell scaling methodology as well as process innovation. In order to increase cell density, there are several different ways pursued in terms of vertical and lateral scaling. As the cell spacing becomes closer, process innovation is a driver for continuing to drive reliable cell performance, but the resultant higher cell density needs to be achieved at a reasonable cost of ownership.

Furthermore, to increase integration in 3D NAND, logical (single layer cells SLC, multi-level cells MLC, triple-level cells TLC, quad-level cells QLC, penta-level cells PLC), vertical stacks, lateral rows, and structural (four dimensional structures, Periphery under Cell Array (PUA), Hybrid Wafer Bonding (HWB)) scaling are in progress. However, the present invention has recognized that the efforts to increase integration are reaching their limits in terms of physically-achievable dimensions and cost. Accordingly, in embodiments of the present invention, physical scaling methods through the formation of multi-site cells are described to address these issues. In one embodiment of the present invention, Multi-Site Cell (MSC) structures provided by channel cutting (with storage nodes and discrete cells formed by non-conformal oxide and carbon gap-fill operations) provide a channel area at least greater than 50% of a conventional NAND device. A conventional NAND device has a channel area of approximately 5000 nm². In another embodiment, the channel area can be greater than 60% of such a conventional NAND device. In another embodiment, the channel area can range from 40% and 70% of such a conventional NAND device.

In one embodiment of the present invention, overall cell reliability performances (e.g., like retention and charge trapping as well as other device metrics like program saturation) are met. In an additional embodiment, the present invention provides configurations and methods for forming multi-site cells (MSC) for advanced NAND technology scaling to support future artificial intelligence (AI) and high-end data center market segments.

This invention in one embodiment includes a method that can improve cell characteristics by discretizing a sufficient storage node area recessed through a sacrificial blocking layer, while cutting the channel poly-Si of a string of memory elements by non-conformal oxide and carbon gap-fill operations. In one embodiment, this process of cutting the channel poly-Si by non-conformal oxide and carbon gap-fill operations is optimized (e.g., by varying the channel area and cell separation in the string of memory elements) to reduce current degradation which can occur if, during the formation of the string of memory elements, channel cutting of the poly-Si unnecessarily removes a width of the poly-Si used for carrying current in the string of memory elements.

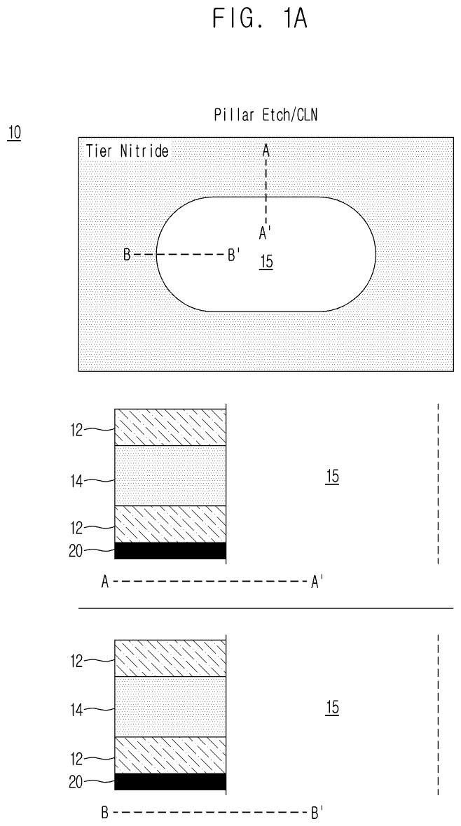

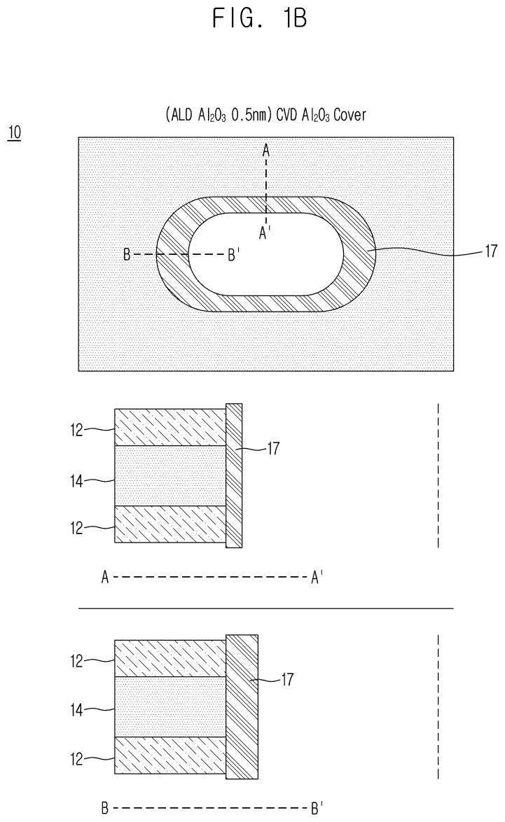

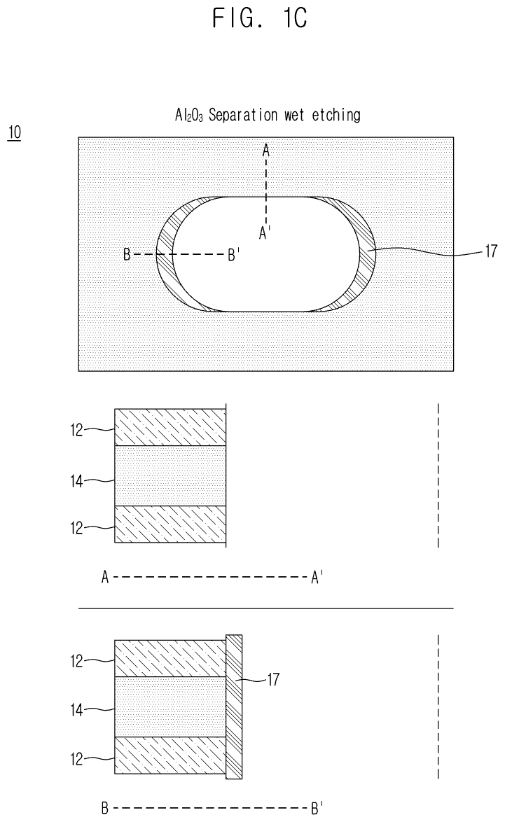

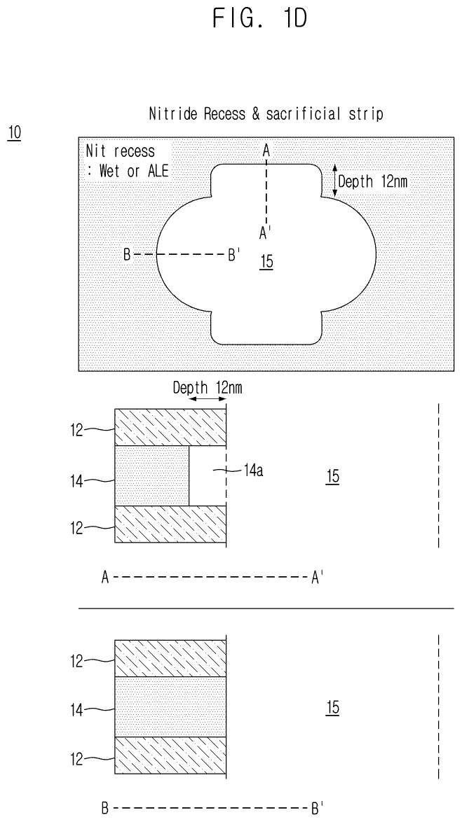

FIG. 1A is a diagram depicting processing an elliptical or oval cell shape. While depicting an elliptical or oval cell shape, the present invention is not limited to these shape, but can be used with other asymmetric shaped holes such as for example triangular, quadruple, or star shaped holes.

As shown in FIG. 1A, a stacked alternating oxide/nitride (ON) structure 10 (having at least an oxide 12 and a nitride 14) is provided with an asymmetric opening 15 (in this example an oval) in the center. The asymmetric opening (or hole) has shorter axis sides and longer axis sides. The asymmetry plays a role in assisting in the process of forming a split cell or a multi-split cell as tetraethyl orthosilicate (TEOS) deposition is deposited in recesses, and preferentially in spaces where the dimensions are shorter. The stacked alternating oxide/nitride (ON) structure 10 is formed on a substrate 20. For simplicity, substrate 20 is not shown in the other drawings. The stacked alternating oxide/nitride (ON) structure 10 can be formed with multiple oxide and nitride layers. The stacked alternating oxide/nitride (ON) structure 10 can be formed from a sequence of plasma assisted chemical vapor depositions where the plasma contains during one period of time oxygen and a silicon carrier such as silane and/or disilane, and thereafter contains during another period of time nitrogen and/or ammonia and a silicon carrier such as silane and/or disilane.

The thicknesses of the oxide layers (e.g., 18 nm) and the nitride layer (e.g., 23 nm) are shown in the cross section shown there on FIG. 1A, although the present invention is not limited to the dimensions shown. As shown in FIG. 1B, an aluminum oxide (Al₂O₃) layer 17 is deposited along the interior wall of the stacked ONO structure 10 inside the opening 15, although the present invention is not limited to the dimension shown. For example, the Al₂O₃ layer 17 may have a thickness of 0.5 nm. As shown in FIG. 1B, the thickness of the deposited Al₂O₃ layer 17 is thicker in the B-B′ direction. As shown in FIG. 1C, wet etching removes all of the Al₂O₃ layer 17 along the A-A′ direction and leaves some of the Al₂O₃ layer 17 along the B-B′ direction.

In one embodiment, an atomic layer deposition can be used to deposit Al₂O₃ layer 17. Process parameters for the atomic layer deposition optimized for non-conformality include (but are not limited to) the precursor amount from Al sources, such as for example trimethyl aluminum (TMAI) and aluminum trichloride (AlCl₃), the amount of oxygen from for example O₃ and O₂ sources, the deposition temperatures (for example ranging from 300° C. to 750° C.), and the deposition pressures (typically at or below atmospheric pressure). The process parameters can vary depending on the specific deposition tool configuration used for the Al₂O₃ deposition, and the present invention is not limited to the Al₂O₃ deposition parameters given here.

As shown in FIG. 1D, after a nitride etch and further after removal of the Al₂O₃ layer 17, some of the nitride from the nitride layer 12 along the A-A′ direction was removed (as this section is not protected by any of the Al₂O₃ layer 17) to form recesses 14a between oxides 12. The recesses 14a represent a recessed pockets between oxides 12 that are later filled with components for data storage. The nitride layer 12 along the B-B′ direction was not etched (as this section was protected by the Al₂O₃ layer 17).

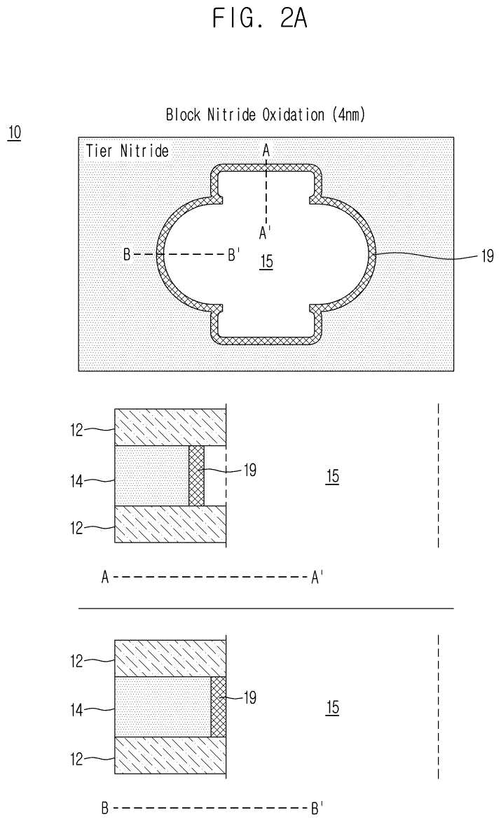

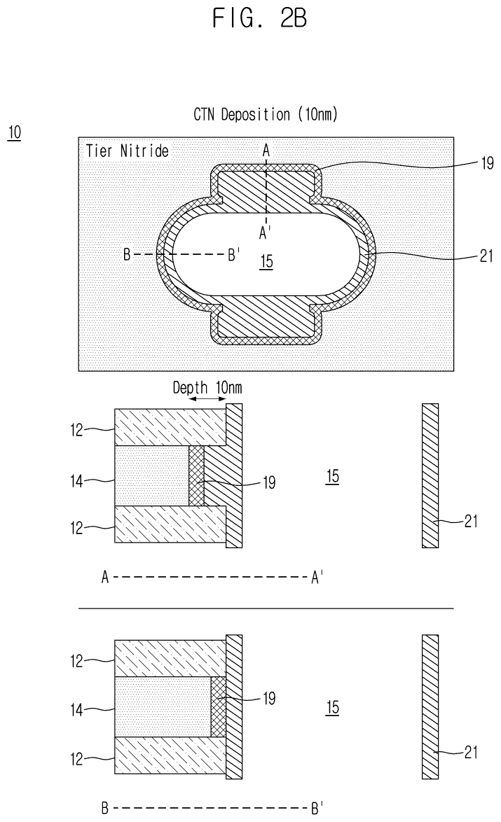

As shown in FIG. 2A, the nitride layer is oxidized for example by exposure to oxygen species from an oxygen plasma to create a relatively thin silicon oxide layer 19. As shown along the section in the A-A′ direction, silicon oxide layer 19 exists in a recess 14a between the oxide layers 12. As shown in FIG. 2B, a charge trap nitride (CTN} deposition is formed on the silicon oxide layer 19 to form a silicon nitride 21. The silicon nitride 21 may have a thickness of 10 nm. In one embodiment, the silicon nitride 21 exists in recess 14a between the oxide layers 12, and functions as a charge trap in the completed memory device. The silicon nitride deposition conditions to form silicon nitride 21 may vary depending on the specific tool configuration being used for the silicon nitride deposition. In general, there are several options for silicon nitride deposition including the use of large batch CVD furnace (>100 wafers boat) or small batch CVD furnace (<50 wafers boat) or single wafer or multi-station ALD deposition tools. Deposition temperatures can range from approximately 500° C.-850° C. depending on the heater configuration used in the deposition tools. The precursors used for the deposition of silicon nitride 21 can be silane or dicholorosilane along with NH₃. The deposition pressures are typically at or below atmospheric pressure. The process parameters in terms of pressure, temperature, and precursor flow (etc.) can vary, and the present invention is not limited to the silicon nitride deposition parameters given here.

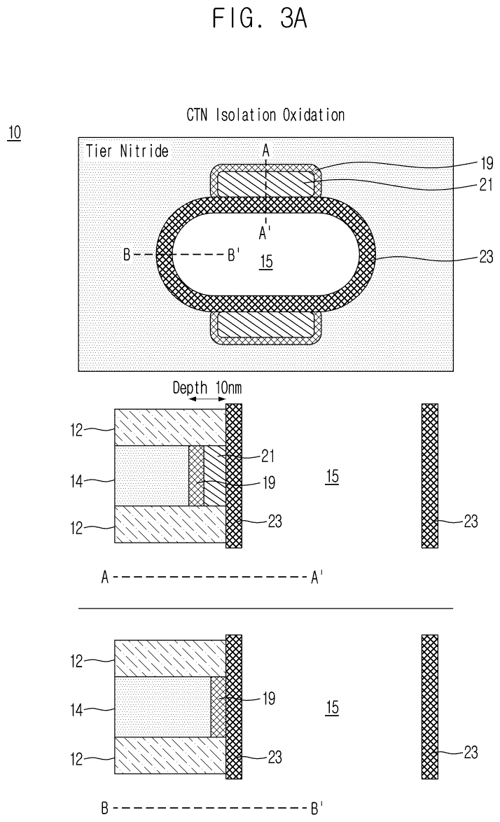

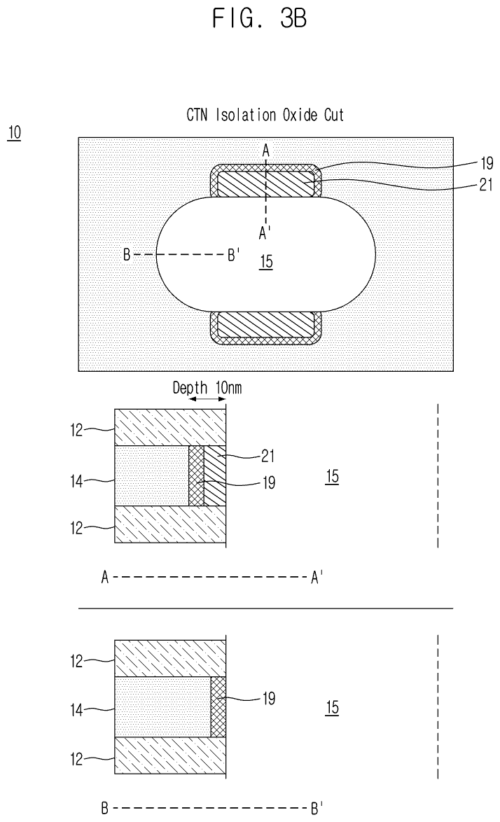

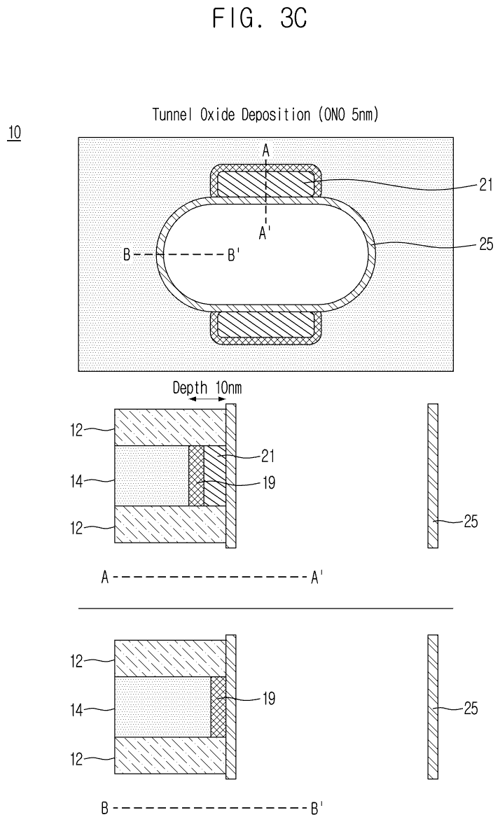

As shown in FIG. 3A, silicon nitride 21 is oxidized using for example exposure to oxygen species from an oxygen plasma to form oxide layer 23. As shown in FIG. 3A, the oxide layer 23 extends to oxide 12 and contacts silicon nitride 21 in between oxides 12 in the stacked alternating oxide/nitride (ON) structure 10, as seen in the A-A′ direction. As shown in FIG. 3B, the oxide layer 23 is removed for example by wet etching, leaving in the A-A′ direction silicon nitride 21 exposed to opening 15 and leaving in the B-B′ direction oxide layer 19 exposed to opening 15. As shown in FIG. 3C, an oxide 25 is formed on silicon nitride 21 forming an oxide layer 19/nitride 21/oxide 25 (a tunneling ONO structure) in the A-A′ direction. Oxide 25 in the B-B′ direction covers the wall of the opening 15 in the stacked alternating oxide/nitride (ON) structure 10. FIG. 3C shows a thickness 5 nm of for the oxide 25, although the present invention is not limited to this thickness.

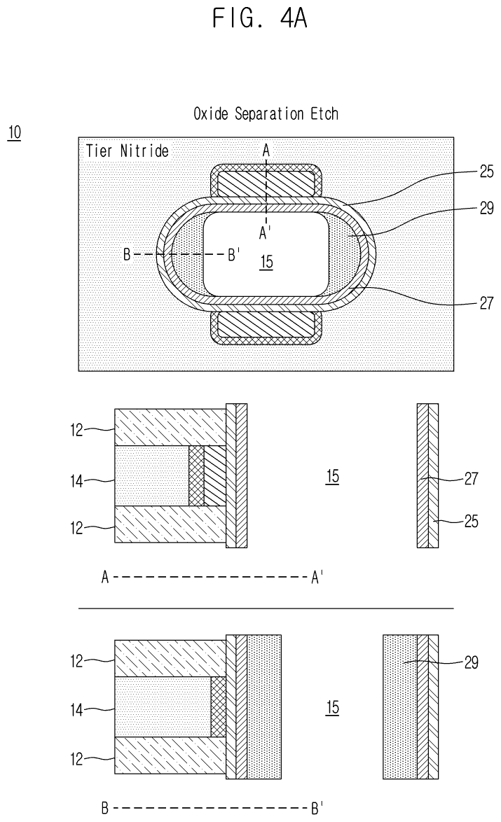

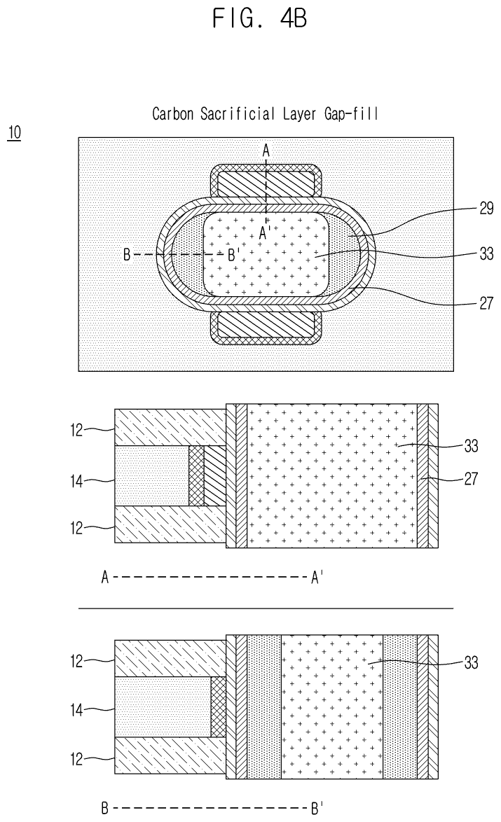

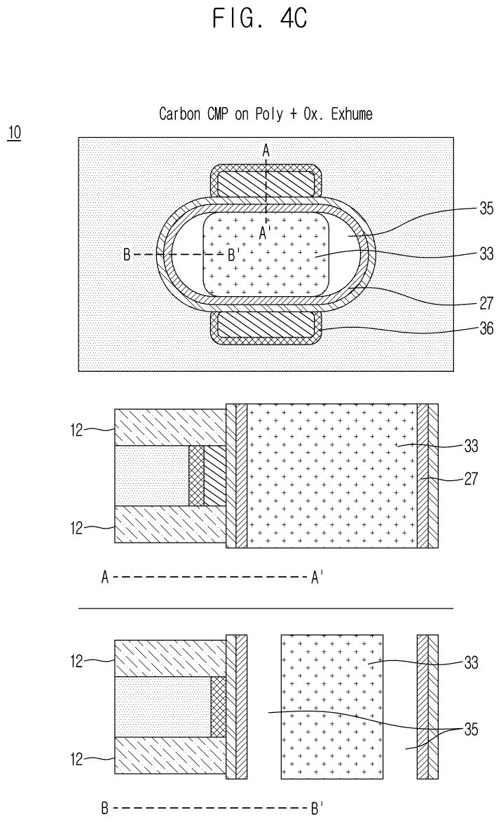

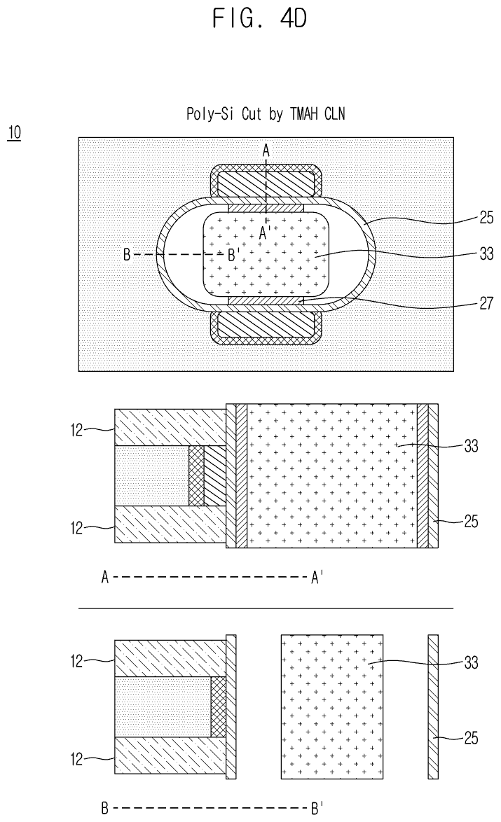

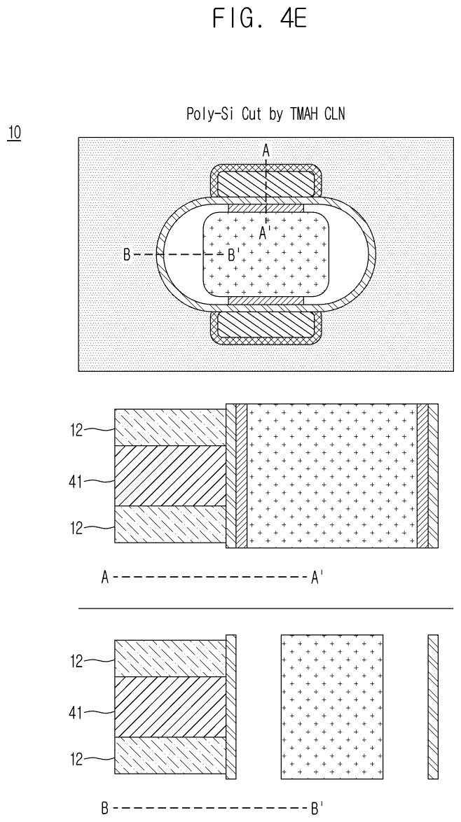

As shown in FIG. 4A, a poly-silicon layer 27 is formed on a wall of the oxide 25. Amorphous silicon can be deposited on the wall of the oxide 25, using for example a plasma chemical vapor deposition process with silane gas as the source of silicon. The amorphous silicon can be annealed to form poly-silicon layer 27. Alternatively, a poly-silicon layer 27 can be directly deposited using the plasma chemical vapor deposition process on the wall of the oxide 25. Subsequently, a pillar oxide fill 29 is formed filling a part of the opening 15. Pillar oxide fill 29 protects etching of oxide 25 during subsequent processing. As shown in the results depicted in FIG. 4B, the opening 15 is filled with carbon for example by a Spin on Carbon (SOC) process or photo-resist (PR) coating. Then, the top area of the carbon fill layer 33 (or the PR) is removed by CMP or wet cleaning process. After that, oxide 12 is exhumed (i.e., removed) by a wet cleaning process. As shown in the B-B″ section, a part of the opening 15 remains against the shorter side of the hole. Then, the channel poly-silicon layer 27 exposed by opening 15 is removed by wet cleaning to cut the channel. Due to the asymmetry, the carbon fill layer 33 preferentially fills in the shorter A-A′ direction forming offset gaps 35. Carbon fill layer 33 can be formed using plasma enhanced chemical vapor deposition PECVD or a flowable chemical vapor deposition CVD technique using for example C₂H₂ or C₃H₆ as the carbon precursors. The deposition temperature can range approximately from 200° C. to 400° C. The deposition pressures are typically at or below atmospheric pressure. The process parameters in terms of pressure, deposition temperature, and precursors flow (etc.) can vary depending on the specific tool configuration, and the present invention is not limited to the carbon fill deposition parameters given here.

Furthermore, in other embodiments, different gap-filling materials besides carboncan be used. These alternative gap-filling materials may include materials such as tetraethyl orthosilicate TEOS, polysilazane PSZ (or other inorganic materials), flowable oxide fill materials like SiOC, carbon based film such as SiC or SiCN, amorphous carbon or other similar materials, where the step coverage or conformality (top to bottom sidewall coverage) can be tuned.

As shown in FIG. 4C, the poly-silicon layer 27 can be considered as a sacrificial poly-silicon layer and a channel cell poly-silicon layer. As shown in FIG. 4D, the sacrificial poly-silicon layer is removed by etching around the carbon fill layer 33 leaving the channel cell poly-silicon layer. As shown in FIG. 4E, a metallic lead 41 can be formed in recesses between oxide layer 12. Afterwards or before or during the process of forming the metallic lead 41. the carbon fill layer 33 can be removed. Accordingly, in one embodiment of the present invention, the cell is split into two halves. Different cell structure geometries such as triangular, quadruple, and star-shaped structures, etc., with the narrow sections can be used to split the cell structure into multiple cells.

Accordingly, in one embodiment, after an alternating ON stack is formed, the first process in forming a cell is a pillar etching which (according to the present invention) can produce for the cell various shapes such as for example an elliptical oval, triangular, quadruple, or star shapes. Then, a sacrificial blocking layer is deposited to form a recessed pocket area. At this time, this sacrificial blocking layer needs to have dry and wet etching selectivity with respect to the ONON stacks. The blocking layer can include metal oxide, oxide, nitride, un-doped poly-Si, or metal films, taking into account the ONON stacks. The blocking layer can include the Al₂O₃ layer described above.

To recess one of the tier nitride layers in the ONON structure, the sacrificial blocking layer is separated through a dry or wet etching process. The isotropic etching method is used to separate each layer using the deposition characteristics of the sacrificial blocking layer, which has a thicker thickness in a narrow area.

After etching, this sacrificial blocking layer remains only at the narrow area in the dual, triple, quadruple, or more shapes. The tier nitride layer (to make pocket area) can be selectively separated through dry or wet etching using the separated blocking layer as a barrier. After tier nitride recess process, remaining sacrificial blocking layers need to be removed by a dry or wet etching process which has enough selectivity between sacrificial layers and tier oxide/nitride. Then, a blocking oxide is deposited for electrical insulation from the WL (Word Line), and an additional nitride layer (that acts as a storage node) is deposited at the recessed pocket as well as the pillar sidewall area. To remove the nitride film deposited on the pillar sidewall, additional oxidation and wet cleaning processes or dry etching (which has enough selectivity between tier oxide and nitride) can be performed to strip the remaining nitride in areas other than the pocket area. Then, each physically separated storage layer acts as an individual cell.

Afterwards, a tunnel oxide is formed by the ONO deposition tool at one time, and then a channel poly-Si is applied. To cut the channel area by sacrificial non-conformal oxide deposition, the non-conformal oxide layer is separated by a dry or wet separation process at a thin oxide area instead of a thick oxide area.

To cover the channel poly-Si, the opened area (in one embodiment) is filled with carbon by a SOC (Spin on Carbon) or photo-resist PR coating process. Then, the top area carbon or the PR is removed by CMP or wet cleaning process. After that, the opened oxide is exhumed (or otherwise removed) by a wet cleaning process, and then the opened channel poly-Si is removed by wet cleaning to cut the poly-Si channel. Through this process flow, the narrow channel area of prior channel-cutting MSC can be improved as the channel areas are no longer in narrow sections of the divided memory cell. At the same time, a channel can be independently formed in in each multi slit cell.

### Split Cell Formation

In accordance with embodiments of the present invention, there is provided a method for dividing a recessed pocket-type storage layer (a discrete cell) by use of sacrificial blocking layers (such as non-conformal oxide and carbon/PR coating) without an oxidation cut process which may oxidize the charge trap nitride (CTN) during a channel poly-Si oxidation/cut process. Also, this method in one embodiment can secure storage nodes of sufficient areas (as noted above) to store and retain charge in each split storage section.

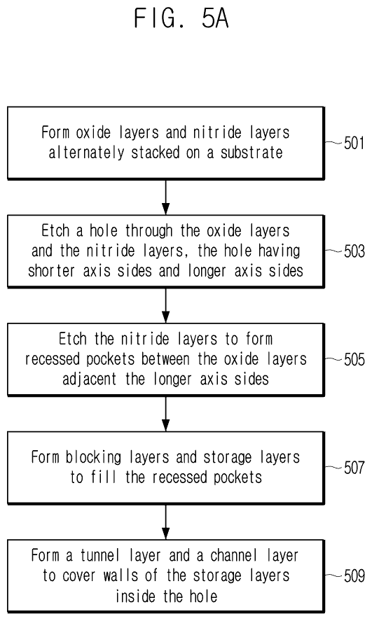

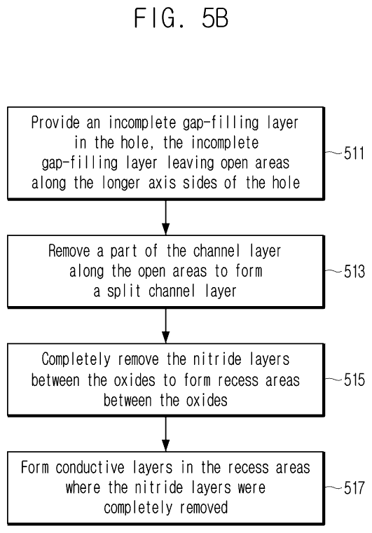

FIGS. 5A and 5B represent a composite flow chart depicting a method for forming a split storage structure in accordance with one embodiment of the present invention.

At 501, the method forms oxide layers and nitride layers alternately stacked on a substrate. At 503, the method etches the oxide layers and the nitride layers to form a hole having shorter axis sides and longer axis sides. At 505, the method forms recessed pockets within the nitride layers adjacent the longer axis sides. At 507, the method forms blocking layers and storage layers to fill the recessed pockets. At 509, the method forms a tunnel layer and a channel layer to cover vertical walls of the storage layers inside the hole. At 511, the method provides an incomplete gap-filling layer in the hole, the gap-filling layer leaving open areas along the longer axis sides. The incomplete gap-filling layer represents a non-optimized or poor step coverage gap-filling layer. At 513, the method selectively removes a part of the channel layer along the open areas to form a split channel layer. At 515, the method removes the nitride layers to form recesses between the oxides. At 517, the method forms conductive layers in the recesses where the nitride layers are removed.

In one embodiment, the providing of the incomplete gap-filling layer comprises providing a carbon fill layer in the hole.

In another embodiment, forming a channel layer comprises forming silicon for the channel layer. In a further embodiment, this method removes the part of the channel layer by etching the silicon in the part of the channel layer. The etching of the silicon uses a non-oxidation process to remove the silicon. The non-oxidation process avoids dimensional changes to the blocking layers and storage layers from additional oxidation

In another embodiment, the forming of the silicon comprises depositing amorphous silicon and thereafter annealing the amorphous silicon to form polycrystalline silicon. Alternatively, the forming silicon may deposit polycrystalline silicon.

In another embodiment, a first blocking layer of the blocking layers, a first storage layer of the storage layers, the tunnel layer, and a first half of the split channel layer can form a first storage structure. Furthermore, a second blocking layer of the blocking layers, a second storage layer of the storage layers, the tunnel layer, and a second half of the split channel layer can form a second storage structure.

In another embodiment, the first storage structure and the second storage structure form a multi-cell storage structure.

In another embodiment, the forming of the tunnel layer comprises forming an oxide/nitride/oxide dielectric. In another embodiment, the forming of the blocking layers comprises forming silicon oxides in between the oxide layers. In another embodiment, the forming of the storage layers comprises forming silicon nitride layers in between the oxide layers.

In another embodiment, prior to the forming of the recessed pockets, an alumina film can be deposited on vertical walls of the hole along the shorter axis sides and along the longer axis sides, and a thickness of the alumina film along the shorter axis sides is thinner than the alumina film along the longer axis sides. Further, the forming the recessed pocket areas may comprise etching the alumina film from both the longer and shorter axis sides, and afterwards, etching a part of the nitride from the nitride layers between the oxide layers to form the recessed pocket areas.

### Memory System(s)

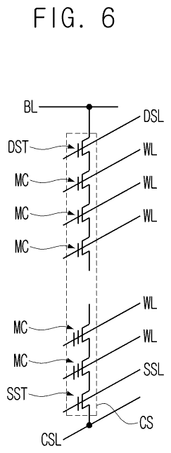

Referring to FIG. 6, the semiconductor memory device of the present invention may be a three-dimensional (3D) nonvolatile memory device or a two-dimensional (2D) nonvolatile memory device. According to one embodiment, the nonvolatile memory device may be a NAND flash memory device. The NAND flash memory device may include a memory cell string CS coupled to a bit line BL and a common source line CSL.

FIG. 6 illustrates a single memory cell string CS, but a plurality of memory cell strings may be coupled in parallel between the bit line BL and the common source line CSL. The memory cell string CS may include a source select transistor SST, a plurality of memory cells MC, and a drain select transistor DST disposed between the common source line CSL and the bit line BL. Each of the memory cells MC may comprise one of the memory structures described above with reference to FIGS. 1-5.

The source select transistor SST may control the electrical coupling between the plurality of memory cells MC and the common source line CSL. A single source select transistor SST may be disposed between the common source line CSL and the plurality of memory cells MC. Two or more source select transistors coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL. Each of the memory cells MC may store single-bit data or multi-bit data.

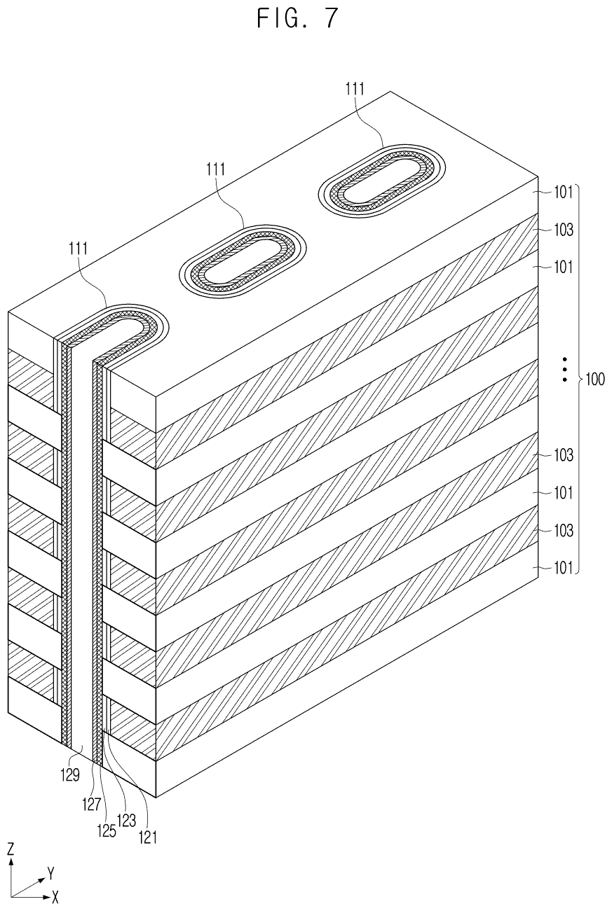

Referring to FIG. 7, the semiconductor memory device of the present invention may include a stacked body 100, a channel layer 127 (corresponding to split channel layer 27 in FIG. 4D), a tunnel insulating layer 125 (corresponding to tunnel oxide 25 in FIG. 3C), a data storage or charge trap layer 123 (corresponding to silicon nitride 21 in FIG. 3D), and a blocking insulating layer 121 (corresponding to oxide 19 in FIG. 3C).

The stacked body 100 may include interlayer insulating layers 101 and word lines 103 (corresponding to metallic line 41 in FIG. 4E) in contact with blocking insulator 121. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103.

The word lines 103 may be insulated from each other by the interlayer insulating layers 101. The word lines 103 may be used as the gate electrodes of the memory cells MC described with reference to FIG. 1, The word lines 103 may include at least one of a doped semiconductor, metal, a metal nitride, and a metal silicide. The interlayer insulating layers 101 may include a silicon oxide layer.

The stacked body 100 may be penetrated by a hole 111 extending in the Z-axis direction. The sidewalls of the interlayer insulating layers 101 may be defined along the sidewall of the hole 111. Oxide 129 (such as oxide fill 29 in FIG. 4B) can fill the space in hole 111.

### Different Configurations

The present invention is not limited to the oval divided memory cell configuration(s) shown above. In one embodiment, the divided memory cell configuration (or multi-site cell structures) can have a triangular shape with charge traps (charge trap layer 123 or silicon nitride 21) disposed in recesses adjacent the triangular sides. In another embodiment, the divided memory cell configuration can have a quadruple shape with charge traps (charge trap layer 123 or silicon nitride 21) disposed in recesses adjacent the quadruple sides. In another embodiment, the divided memory cell configuration can have a pentagonal shape with charge traps (charge trap layer 123 or silicon nitride 21) disposed in recesses adjacent the quadruple sides. In another embodiment, the divided memory cell configuration can have a hexagonal shape with charge traps (charge trap layer 123 or silicon nitride 21) disposed in recesses adjacent the hexagonal sides.

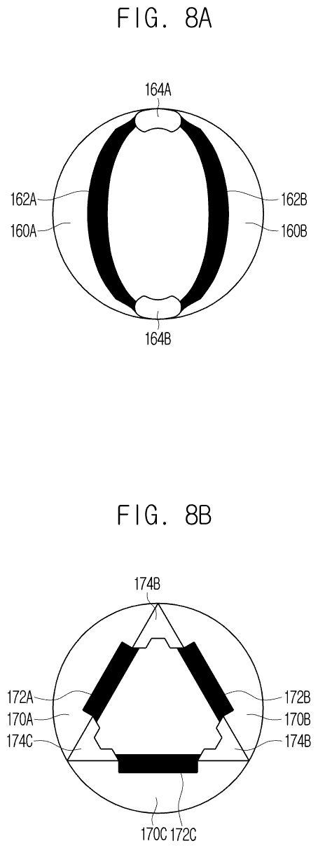

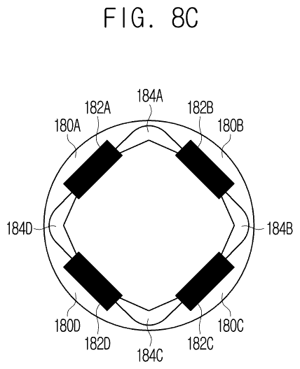

More specifically, FIGS. 8A to 8C are schematic diagrams of multi-site cell structures of a semiconductor memory device in accordance with different embodiments of the present disclosure.

As shown in FIG. 8A, the multi-site cell structure may include a dual site (or slit) cell. As shown in FIG. 8B, the multi-site cell structure may include a triple site cell. As shown in FIG. 8C, the multi-site cell structure may include a quadruple site cell. Alternatively, the multi-site cell structure may include a pentagon site cell or a hexagon site cell.

Referring to FIG. 8A, the dual site cell structure may include two cell patterns 160A, 160B. The cell patterns 160A, 160B may include two recessed storage patterns 162A, 162B, respectively. The recessed storage patterns 162A, 162B may have recessed pocket areas, which are separated by separation layers 164A, 164B. Each storage pattern can act as an independent cell. These elements and the process for forming the dual site cell structure have been described above with reference to FIGS. 1A to 4B.

Referring to FIG. 8B, the triple site cell structure may include two cell patterns 170A, 170B, 170C. The cell patterns 170A, 170B, 170C may include three recessed storage patterns 172A, 172B, 172C, respectively. The recessed storage patterns 172A, 172B, 172C may have recessed pocket areas, which are separated by separation layers 174A, 174B, 174C. Each storage pattern can act as an independent cell.

Referring to FIG. 8C, the quadruple site cell structure may include four cell patterns 180A, 180B, 180C, 180D. The cell patterns 180A, 180B, 180C, 180D may include four recessed storage patterns 182A, 182B, 182C, 182D, respectively. The recessed storage patterns 182A, 182B, 182C, 182D may have recessed pocket areas, which are separated by separation layers 184A, 184B, 184C, 184D. Each storage pattern can act as an independent cell.

### Semiconductor Memory Device(s)

Accordingly, in one embodiment of the present invention, there is provided a semiconductor memory device comprising: a split channel layer adjacent an asymmetric hole in a stacked structure; a tunnel oxide in contact with the split channel layer; a charge trap disposed in the stacked structure and in contact with the tunnel oxide, a blocking oxide disposed in a recess in the stacked structure adjacent the asymmetric hole and in contact with the charge trap, wherein the split channel layer is divided from a silicon channel layer using a non-oxidation process such that dimensions of the charge trap and the blocking layer from respective patterned dimensions are not changed due to additional oxidation.

In another embodiment, the split channel layer comprises a first channel layer disposed along a first longer axis side of the asymmetric recess and a second channel layer disposed along a second longer axis side of the asymmetric recess. Further, the blocking oxide, the charge trap, the tunnel oxide, the first channel layer, and the second channel layer comprise a multi-cell memory storage structure for the semiconductor memory device.

In another embodiment, the asymmetric recess has a longer axis side and a shorter axis side, wherein a ratio of the longer axis side to the shorter axis side ranges from 2 to 10.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiment. Furthermore, the disclosed embodiments may be combined to form additional embodiments.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for forming a split storage structure, comprising:
forming oxide layers and nitride layers alternately stacked on a substrate;
etching a hole through the oxide layers and the nitride layers, the hole having shorter axis sides and longer axis sides;
etching the nitride layers to form recessed pockets between the oxide layers adjacent the longer axis sides;
forming blocking layers and storage layers to fill the recessed pockets;
forming a tunnel layer and a channel layer to cover walls of the storage layers inside the hole;
providing an incomplete gap-filling layer in the hole, the incomplete gap-filling layer leaving open areas along the longer axis sides of the hole;
removing a part of the channel layer along the open areas to form a split channel layer;
completely removing the nitride layers between the oxide layers to form recesses between the oxide layers; and
forming conductive layers in the recesses where the nitride layers were completely removed.

2. The method of claim 1, wherein the providing of the incomplete gap-filling layer comprises providing a carbon fill layer in the hole.

3. The method of claim 1, wherein the forming of the channel layer comprises forming silicon for the channel layer.

4. The method of claim 3, wherein the removing of the part of the channel layer comprises etching the silicon in the part of the channel layer.

5. The method of claim 3, wherein the etching of the silicon comprises using a non-oxidation process to remove the silicon.

6. The method of claim 5, wherein the non-oxidation process avoids dimensional changes to the blocking layers and storage layers from additional oxidation.

7. The method of claim 3, wherein the forming of the silicon comprises depositing amorphous silicon and thereafter annealing the amorphous silicon to form polycrystalline silicon.

8. The method of claim 3, wherein the forming of the silicon comprises depositing polycrystalline silicon.

9. The method of claim 1, wherein a first blocking layer of the blocking layers, a first storage layer of the storage layers, the tunnel layer, and a first half of the split channel layer form a first storage structure.

10. The method of claim 9, wherein a second blocking layer of the blocking layers, a second storage layer of the storage layers, the tunnel layer, and a second half of the split channel layer form a second storage structure.

11. The method of claim 10, wherein the first storage structure and the second storage structure form a multi-cell storage structure.

12. The method of claim 1, wherein the forming of the tunnel layer comprises forming an oxide/nitride/oxide dielectric.

13. The method of claim 1, wherein the forming of the blocking layers comprises forming silicon oxides in between the oxide layers.

14. The method of claim 1, wherein the forming of the storage layers comprises forming silicon nitride layers in between the oxide layers.

15. The method of claim 1, wherein
prior to the forming of the recessed pockets, depositing an alumina film on vertical walls of the hole along the shorter axis sides and along the longer axis sides, and
a thickness of the alumina film along the shorter axis sides is thinner than the alumina film along the longer axis sides.

16. The method of claim 15, wherein the forming of the recessed pockets comprises:
etching the alumina film from both the longer and shorter axis sides; and
afterwards, etching a part of the nitride from the nitride layers between the oxide layers to form the recessed pockets.

17. A semiconductor memory device comprising:
a split channel layer adjacent an asymmetric hole in a stacked structure, the asymmetric hole having shorter axis sides and longer axis sides;
a tunnel oxide in contact with the split channel layer;
a charge trap disposed in the stacked structure and in contact with the tunnel oxide; and
a blocking oxide disposed in a recess in the stacked structure adjacent the asymmetric hole and in contact with the charge trap,
wherein
the split channel layer is divided from a silicon channel layer, and
spatial dimensions of the charge trap and the blocking layer are not changed during division of the silicon channel layer.

18. The device of claim 17, wherein the split channel layer comprises a first channel layer disposed along a first longer axis side of the asymmetric recess and a second channel layer disposed along a second longer axis side of the asymmetric recess.

19. The device of claim 18, wherein
the blocking oxide, the charge trap, the tunnel oxide, the first channel layer, and the second channel layer comprise a multi-cell memory storage structure for the semiconductor memory device.

20. The device of claim 17, wherein a ratio of the longer axis side to the shorter axis side ranges from 2 to 10.
